(19) United States
(12) Patent Application Publication
(10) Pub. No.: US 2019/0081197 A1
(43) Pub. Date: Mar. 14, 2019

(54) METHOD FOR MANUFACTURING WIDE-BANDGAP OXIDE EPITAXIAL FILM

(71) Applicants: TYNTEK CORPORATION, Hsinchu City (TW); NATIONAL CHIAO TUNG UNIVERSITY, Hsinchu City (TW)

(72) Inventors: RAY-HUA HORNG, HSINCHU (TW); YEN-CHU LI, MIAOLI COUNTY (TW); CHUN-YI TUNG, MIAOLI COUNTY (TW); SI-HAN TSAI, HSINCHU (TW); LI-CHUNG CHENG, HSINCHU (TW)

(21) Appl. No.: 15/878,793

(22) Filed: Jan. 24, 2018

(30) Foreign Application Priority Data
Sep. 12, 2017 (TW) 106131300

(51) Int. Cl. H01L 31/18; H01L 31/032; C30B 29/26; C30B 25/18

(52) U.S. Cl. CPC H01L 31/18; C30B 25/18; C30B 29/26; H01L 31/0321

(57) ABSTRACT

The present invention provides a method for manufacturing a wide-bandgap oxide epitaxial film. An epitaxial film with superior physical properties, such as high saturated drift velocity of electrons, small dielectric constant, high thermal stability, and excellent high-temperature resistance, is formed on a substrate. In addition, because the oxide epitaxial film is grown by metal-organic chemical vapor deposition (MOCVD), the yield is improved significantly and defects in the epitaxy is reduced.

### FIELD OF THE INVENTION

The present invention relates generally to a method for manufacturing oxide, and particularly to a method for manufacturing a wide-bandgap oxide epitaxial film.

### BACKGROUND OF THE INVENTION

As technologies progress day by day, various micro processes and fabrication technologies are developing rapidly and thus enabling various high-tech devices are developing toward the trend of preciseness and miniaturization. The applications of the miniature devices are extensive, including military, industrial, medical, optoelectronic communication, biotechnological, and daily applications. Mobile phones, ink injecting devices in printers, biochips, and various optical communication devices are examples. Due to people's urgent demand in miniature materials, the era has progressed from micrometer (10⁻⁶) range to nanometer (10⁻⁹) range.

In the semiconductor fabrication process according to the prior art, masks are adopted for patterning wafers and semiconductor substrates and forming various semiconductor devices. As the technologies for integrated circuits advance, product miniaturization is made possible, and the density of circuit layout and feature line in semiconductor devices become finer.

Currently, the sterilizing capability of ultraviolet light has been verified. The deep ultraviolet (DUV) light with wavelengths between 200 and 280 nanometers can destroy the bonds of DNA and RNA in bacteria and viruses. The sterilization efficiency can reach 99% to 99.9%. Particularly, the sterilization effect is best for wavelengths between 250 and 270 nanometers.

In recent years, no matter in the academics or industry, based on the outstanding research in the optoelectronic material of aluminum gallium nitride (AlGaN), the developed DUV photodetectors are found to be applicable to biochemical detection, disinfection, sterilization, or military applications. For the devices of the series, AlGaN epitaxial layers with high aluminum ratio are needed. Unfortunately, as the doping ratio of aluminum is increased, the crystal quality will deteriorate. In addition, compared to gallium nitride, the doping efficiency of n-type AlGaN epitaxial layers is lower, making the formation of ohmic contacts in n-type high-aluminum-ration AlGaN epitaxial layers difficult. For DUV sensors, the production yield is lowered as well. Accordingly, it is required to develop a wide bandgap epitaxial material for DUV sensors and improving the epitaxy yield.

To sum up, the present invention provides a method for manufacturing a wide-bandgap oxide epitaxial film. The method provides a novel oxide epitaxial film with superior optoelectronic performance in nanometer fabrication environments.

### SUMMARY

An objective of the present invention is to provide a method for manufacturing a wide-bandgap oxide epitaxial film. The method provides an oxide epitaxial film for providing superior DUV sensing efficiency.

To achieve the above objective, the present invention provides a method for manufacturing a wide-bandgap oxide epitaxial film, which comprises steps of providing a substrate; and providing an oxide epitaxial material and forming an oxide epitaxial film on the substrate using metal-organic chemical vapor deposition (MOCVD). According to the present invention, the oxide epitaxial material provides a preferred bandgap and hence facilitating superior optoelectronic performance.

According to an embodiment of the present invention, the oxide epitaxial film is a single-crystalline thin film.

According to an embodiment of the present invention, the oxide epitaxial material is formed by zinc, gallium, and oxide.

According to an embodiment of the present invention, the adding rate of zinc into the oxide epitaxial material is between 5 and 20 sccm for producing epitaxial films with various ratios.

According to an embodiment of the present invention, the incident angles of X-ray diffraction to the oxide epitaxial film include 18.67, 37.77, and 58.17 degrees.

According to an embodiment of the present invention, the substrate is a sapphire substrate.

According to an embodiment of the present invention, the step of providing an oxide epitaxial material and forming an oxide epitaxial film on the substrate using MOCVD comprises steps of using dioxides to form the oxide epitaxial material; and forming the oxide epitaxial material on the substrate using MOCVD.

According to an embodiment of the present invention, the dioxides include gallium oxide and zinc oxide.

To sum up, the present invention provides a method for manufacturing a wide-bandgap oxide epitaxial film. The method further controls the grown sensing layer by means of the gradients of zinc and gallium oxide epitaxy for providing a wide bandgap for the oxide epitaxial layer and resulting in superior sensing performance.

### BRIEF DESCRIPTION OF THE DRAWINGS

FIG. 1 shows a structural schematic diagram according an embodiment of the present invention;

FIG. 2 shows a flowchart according an embodiment of the present invention;

FIGS. 3A to 3B show schematic diagrams of partial steps according to an embodiment of the present invention;

FIG. 4 shows a schematic diagram of the lattice according to an embodiment of the present invention; and

FIG. 5 shows curves of photocurrents versus wavelengths according to an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

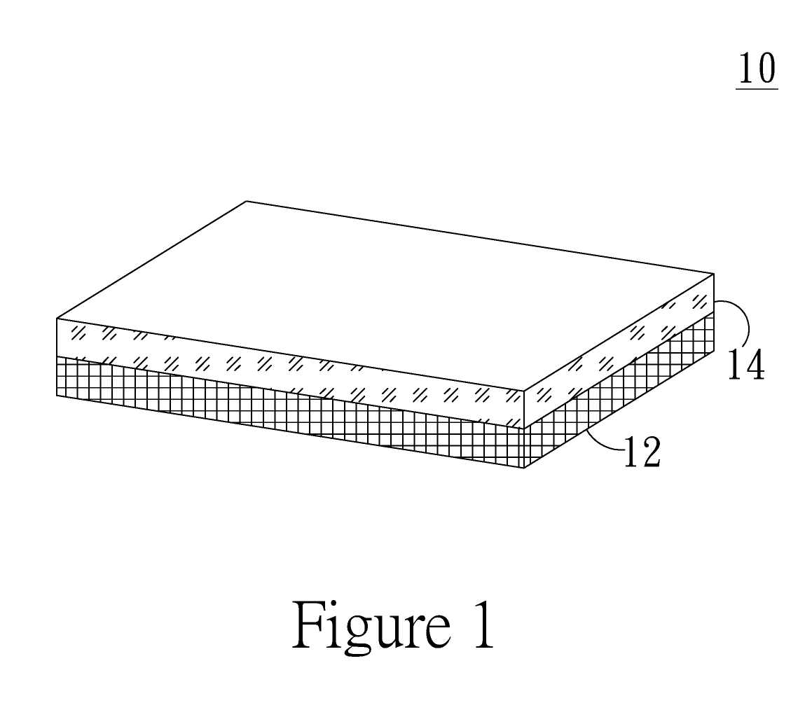

First, please refer to FIG. 1, which shows a structural schematic diagram according an embodiment of the present invention. As shown in the figure, the present invention discloses a wide-bandgap oxide epitaxial structure 10, which comprises a substrate 12 and an oxide epitaxial film 14. The substrate 12 is a sapphire substrate. The oxide epitaxial film 14 is an epitaxial film grown by aerating gas containing zinc at 5 to 20 sccm for producing epitaxial film with various zinc ratios.

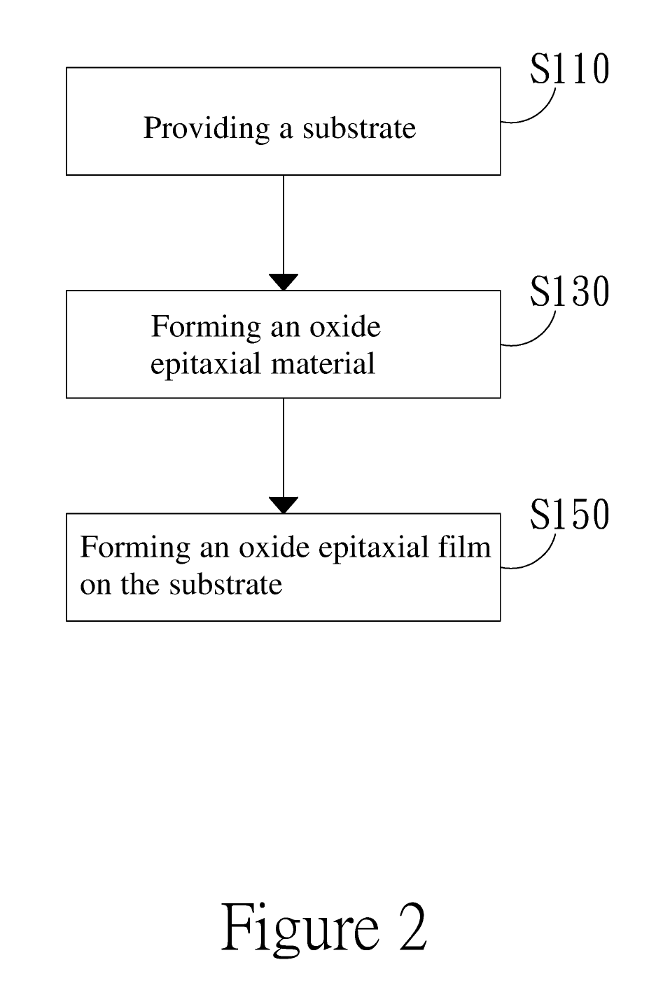

Next, please refer to FIG. 2, which shows a flowchart according an embodiment of the present invention. As shown in FIG. 2 and FIG. 1, the present invention provides a method for manufacturing the wide-bandgap oxide epitaxial film as described above. The method comprises steps of:
Step S110: Providing a substrate;
Step S130: Forming an oxide epitaxial material; and
Step S150: Forming an oxide epitaxial film on the substrate.

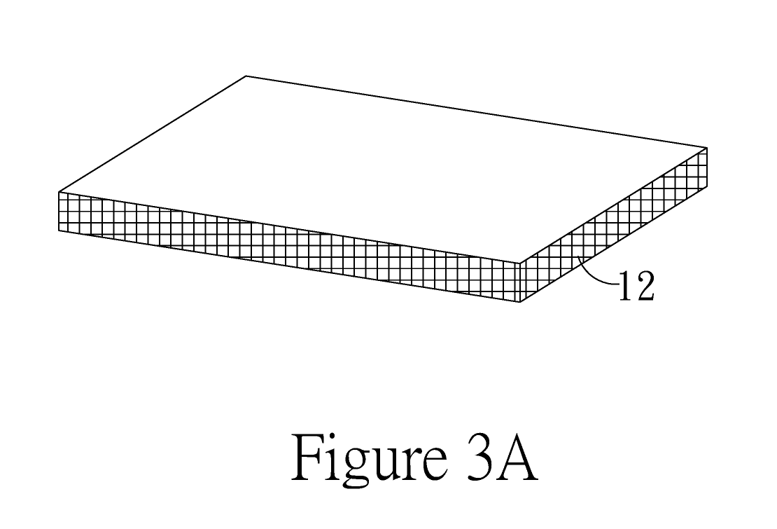

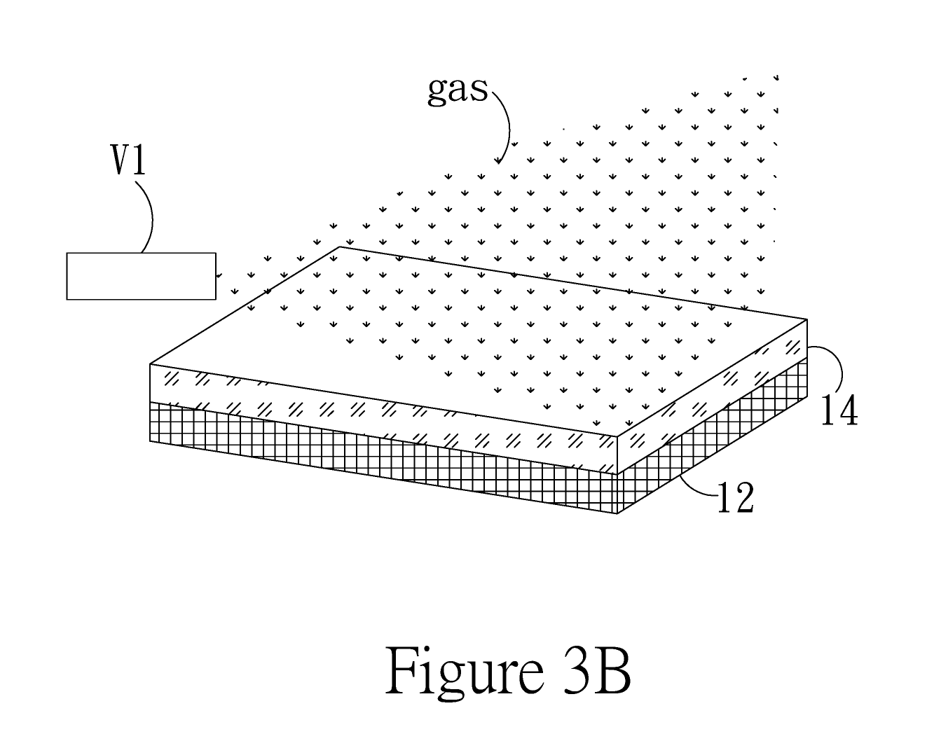

As shown in the step S110 and FIG. 3A, according to the present embodiment, a sapphire substrate is adopted as the substrate 12 of the oxide epitaxial structure 10. The substrate 12 can be a single-crystalline, amorphous, or polycrystalline structure. Next, as shown in the step S130, the oxide of III-V compound semiconductor according to the present embodiment is gallium nitride (Ga₂O₃), making the oxide epitaxial material be zinc gallium oxide (ZnGa₂O₄). Nonetheless, the present invention is not limited to the example; it can alternatively be gallium nitride (GaN). As shown in the step S150 and FIG. 3B, MOCVD is adopted for growing epitaxy on the sapphire substrate. By injecting the gas for the oxide epitaxial material from the nozzle V1 on the epitaxy platform, the oxide epitaxial material can form the oxide epitaxial film 14 on the substrate 12.

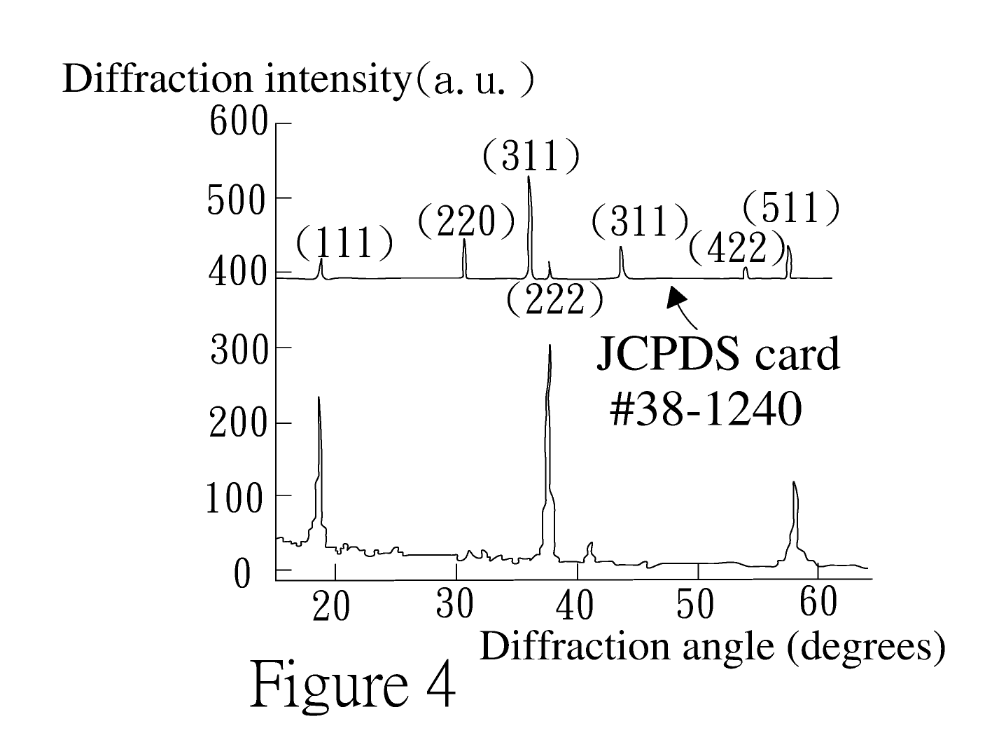

Please refer to FIG. 4, which shows a schematic diagram of the lattice according to an embodiment of the present invention. As shown in the figure, the present invention provides a wide-bandgap oxide epitaxial film, which uses gallium oxide (Ga₂O₃) and zinc oxide (ZnO) to form zinc gallium oxide (ZnGa₂O₄, ZGO), which is a semiconductor material with a wide bandgap of 5 eV. According to the present embodiment, the high breakdown voltage and high saturated drift velocity of electrons of zinc gallium oxide give the sensing device superior optoelectronic properties. The 2θ of zinc gallium oxide has peak values at 18.67, 37.77, and 58.17 degrees. In other words, when the incident angles of X-ray diffraction are 18.67, 37.77, and 58.17 degrees, X-ray diffraction spectrum responses occur. The incident angles are close to those of a standard lattice diagram at 18.4 degree (111), 37.34 degree (222), and 57.4 degree (511) in the card number 38-1240 of the Joint Committee on Powder Diffraction Standards (JCPDS).

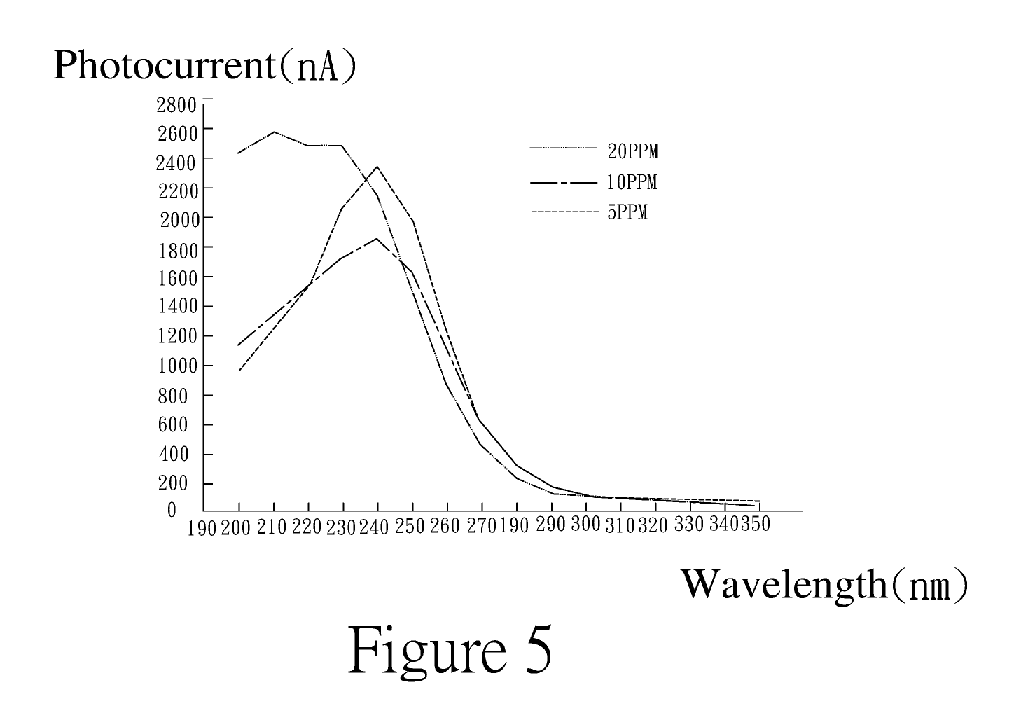

Furthermore, because the substrate 12 is a sapphire substrate, it is beneficial for gallium oxide epitaxy. As shown in FIG. 2, MOCVD is adopted for doping zinc uniformly in the epitaxial structure of gallium oxide and forming a single-crystalline thin film. In addition, as shown in FIG. 5, the gallium oxide according to the present embodiment is doped with zinc. The response of illuminating by ultraviolet light with wavelengths between 150 and 300 nanometers on the oxide epitaxial film 14 grown at 5, 10, and 20 sccm of zinc-containing gas is decent. Namely, the oxide epitaxial film 14 can generate photocurrents at nanoampere level under the stimulation of ultraviolet light.

The present invention provides a method for manufacturing a wide-bandgap oxide epitaxial film. The oxide epitaxial material is used to form the epitaxial film for providing superior optoelectronic properties. In addition, by using MOCVD, the yield of the thin film is improved.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A method for manufacturing a wide-bandgap oxide epitaxial film, comprising steps of:
providing a substrate; and
providing an oxide epitaxial material and forming an oxide epitaxial film on said substrate using metal-organic chemical vapor deposition;
wherein said step of providing an oxide epitaxial material and forming an oxide epitaxial film on said substrate using metal-organic chemical vapor deposition comprises steps of:
zinc oxide doped gallium oxide to form said oxide epitaxial material; and
forming said oxide epitaxial material on said substrate using metal-organic chemical vapor deposition.

2. The method of claim 1, wherein said oxide epitaxial material is formed by the elements including oxygen, gallium, and zinc.

3. The method of claim 2, wherein the adding rate of zinc into said oxide epitaxial material is 5 to 20 sccm.

4. The method of claim 1, wherein said oxide epitaxial film is a single-crystalline thin film.

5. The method of claim 1, wherein the incident angles of X-ray diffraction to said oxide epitaxial film include 18.67, 37.77, and 58.17 degrees.

6. The method of claim 1, wherein said substrate is a sapphire substrate.

7. (canceled)

8. (canceled)
